(19) United States
(12) Patent Application Publication
(10) Pub. No.: US 2021/0140065 A1
(43) Pub. Date: May 13, 2021

(54) SEMICONDUCTOR CRYSTAL GROWTH APPARATUS

(71) Applicant: Zing Semiconductor Corporation, Shanghai (CN)

(72) Inventors: Weimin SHEN, Shanghai (CN); Gang WANG, Shanghai (CN); Xianliang DENG, Shanghai (CN); Hanyi HUANG, Shanghai (CN); Yan ZHAO, Shanghai (CN)

(21) Appl. No.: 17/061,911

(22) Filed: Oct. 2, 2020

(30) Foreign Application Priority Data
Oct. 17, 2019 (CN) 201910990349.7

(51) Int. Cl. C30B 15/14; C30B 29/06; C30B 30/04

(52) U.S. Cl. CPC C30B 15/14; C30B 30/04; C30B 29/06

(57) ABSTRACT

The invention provides a semiconductor crystal growth device. It comprises: a furnace body; a crucible, arranged inside the furnace body to receive the silicon melt; a pulling device arranged on the top of the furnace body, and is used to pulling out the silicon crystal ingot from the silicon melt body; a reflector, being barrel-shaped and disposed above the silicon melt in the furnace in a vertical direction, and the pulling device pulls the silicon crystal ingot passing through the reflector in a vertical direction; and a magnetic field applying device for applying a horizontal magnetic field to the silicon melt in the crucible; wherein the bottom of the reflector is provided with downwardly convex steps, so that a distance between the bottom of the reflector and the silicon melt surface in the direction of the magnetic field is smaller than a distance between the bottom of the reflector and the silicon melt surface in the direction perpendicular to the magnetic field. According to the semiconductor crystal growth device of the present invention, the quality of semiconductor crystal growth is improved.

### CROSS-REFERENCE TO RELATED APPLICATIONS

This application claims priority to P.R.C. Patent Application No. 201910990349.7 titled “a semiconductor crystal growth apparatus” filed on Oct. 17, 2019, with the State Intellectual Property Office of the People's Republic of China (SIPO).

### TECHNICAL FIELD

The present invention relates to the field of semiconductor technology, and in particular, to a semiconductor crystal growth device.

### BACKGROUND

The Czochralski (CZ) method is an important method for preparing single crystal silicon for semiconductor and solar. The high-purity silicon material placed in the crucible is heated by a thermal field composed of a carbon material to melt it, and then the seed is is immersed in the melt and undergoes a series of (seeding, shouldering, body, tailing, cooling) processes to obtain a single crystal ingot.

In the growth of semiconductor single crystal silicon or solar single crystal silicon using the CZ method, the temperature distribution of the crystal and the melt directly affects the quality and growth rate of the crystal. During the growth of CZ crystals, due to the existence of thermal convection in the melt, the distribution of trace impurities is uneven and growth stripes are formed. Therefore, how to suppress the thermal convection and temperature fluctuation of the melt during the crystal pulling process has been a widespread concern.

The crystal growth technology under a magnetic field generator (called MCZ) applies a magnetic field to a silicon melt as a conductor, subjecting the melt to a Lorentz force opposite to its direction of movement, obstructing convection in the melt and increasing the viscosity of the melt reduces impurities such as oxygen, boron, and aluminum from the quartz crucible into the melt, and then into the crystal, so that the grown silicon crystal can have a controlled oxygen content from low to high range, reducing The impurity stripes are widely used in semiconductor crystal growth processes. A typical MCZ technology is so called horizontal magnetic field crystal growth (HMCZ) technology, which applies a horizontal magnetic field to a semiconductor melt, and is widely used for the growth of large-sized and demanding semiconductor crystals.

In the crystal growth technology under a horizontal magnetic field device (HMCZ), the crystal growth furnace, thermal field, crucible, and silicon crystals are as symmetrical as possible in the circumferential direction, and the crucible and crystal rotation make the temperature distribution in the circumferential direction tends to be uniform. However, the magnetic field lines of the magnetic field applied during the application of the magnetic field pass from one end of the silicon melt in the quartz crucible to the other end in parallel. The Lorentz force generated by the rotating silicon melt is different in all directions in the circumferential direction, so the silicon melt flow and temperature distribution are inconsistent in the circumferential direction.

As shown in FIG. 1A and FIG. 1B, schematic diagrams of a temperature distribution below an interface between a crystal grown crystal and a melt in a semiconductor crystal growth apparatus are shown. Among them, FIG. 1A shows a graph of measured test points distributed on the horizontal surface of the silicon melt in the crucible, where one point is tested at an angle of θ=45° at a distance of 25 mm below the melt surface and a distance of L=250 mm from the center. FIG. 1B is a curve of the temperature distribution obtained by simulation calculation and test along each point at an angle θ with the X axis in FIG. 1A, where the solid line represents the temperature distribution map obtained by simulation calculation, and the dot diagram indicates the measured test method adopted distribution of temperature obtained. In FIG. 1A, the arrow A shows that the direction of rotation of the crucible is counterclockwise, and the arrow B shows that the direction of the magnetic field crosses the diameter of the crucible along the Y-axis direction. It can be seen from FIG. 1B that during the growth of the semiconductor crystal, both the results of the simulation calculation and the measured test method have shown that the temperature fluctuated on the circumference below the semiconductor ingot and the melt surface changes with the angle during the growth of the semiconductor crystal.

According to the Voronkov crystal growth theory, the thermal equilibrium equation of the interface of the crystal and the melt surface is as follows,

PS*LQ=Kc*Gc−Km*Gm.

Among them, LQ is the potential of silicon melt to silicon crystal phase transition, Kc, Km represent the thermal conductivity of the crystal and the melt, respectively; Kc, Km, and LQ are the physical properties of the silicon material; PS represents the crystal crystallization speed along the on-pull elongation direction that is approximately the pulling speed of the crystal; Gc, Gm are the temperature gradient (dT/dZ) of the crystal and the melt at the interface, respectively. Because the temperature below the interface of the semiconductor crystal and the melt exhibits periodic fluctuations with the change of the circumferential angle during the growth of semiconductor crystals, that is, the Gc of the temperature gradient (dT/dZ) of the crystal and the melt as the interface, Gm fluctuates. Therefore, the crystallization speed PS of the crystal in the circumferential angle direction fluctuates periodically, which is not conducive to controlling the quality of crystal growth.

For the reasons above, it is necessary to propose a new semiconductor crystal growth device to solve the problems in the prior art.

### SUMMARY

A series of simplified forms of concepts are introduced in the Summary of the Invention section, which will be described in further detail in the Detailed Description section. The summary of the invention is not intended to limit the key features and essential technical features of the claimed invention, and is not intended to limit the scope of protection of the claimed embodiments.

An objective of the present invention is to provide a semiconductor crystal growth apparatus, the semiconductor crystal growth apparatus comprises:
a furnace body;
a crucible being arranged inside the furnace body to contain a silicon melt;
a pulling device being arranged on the top of the furnace body and used for pulling out a silicon ingot from the silicon melt;
a reflector being barrel-shaped and disposed above the silicon melt in the furnace body in a vertical direction,
wherein the pulling device pulls the silicon ingot through the reflector in a vertical direction; and
a magnetic field applying device for applying a horizontal magnetic field to the silicon melt in the crucible;
wherein the bottom of the reflector is provided with downwardly convex steps, so that a distance between the bottom of the reflector and the silicon melt surface in the direction of the magnetic field is smaller than a distance between the bottom of the reflector and the silicon melt surface in a direction perpendicular to the magnetic field.

In accordance with some embodiments, the steps are arranged on opposite sides of the reflector along the direction of the magnetic field.

In accordance with some embodiments, the steps are arc-shaped steps and arranged along the circumferential direction of the reflector.

In accordance with some embodiments, an angle corresponding to the arc-shaped steps is in the range of 20°-160°.

In accordance with some embodiments, a height of the steps is in the range of 2-20 mm.

In accordance with some embodiments, the reflector comprises an inner cylinder, an outer cylinder, and a heat insulating material; wherein the bottom of the outer cylinder is extended below the bottom of the inner cylinder and is closed to the bottom of the inner cylinder to form a cavity between the inner cylinder and the outer cylinder, and the heat insulation material is disposed in the cavity.

In accordance with some embodiments, the bottom of the outer cylinder has different wall thicknesses to form downwardly convex steps at the bottom of the reflector.

In accordance with some embodiments, the reflector comprises an inserting part, the inserting part comprises a protruding portion and an inserting portion, and the inserting portion is inserted between a portion of the bottom of the outer cylinder extended below the bottom of the inner cylinder and the bottom of the inner cylinder, and the protruding portion is extended to cover the bottom of the outer cylinder.

In accordance with some embodiments, the protruding portion comprises two sections disposed on opposite sides of the reflector along the direction of the magnetic field, and the protruding portion constitutes the steps.

In accordance with some embodiments, the protruding portion is ring-shaped and covers the bottom of the reflector, and the steps are located on the protruding portion.

According to the semiconductor crystal growth device of the present invention, by setting the distance between the bottom of the reflector and the silicon melt surface in the direction of the magnetic field is smaller than the distance between the bottom of the reflector and the silicon melt surface in a direction perpendicular to the magnetic field, the heat dissipation speed of the silicon melt surface in the direction of the magnetic field is greater than the heat dissipation speed of the silicon melt surface in the direction perpendicular to the magnetic field, so that the temperature distribution of the silicon melt below the silicon ingot and the silicon melt interface is effectively tuned. Therefore, the temperature distribution of the silicon melt below the interface between the silicon ingot and the silicon melt is tuned, such that the problem of fluctuations in the temperature distribution of the silicon melt below the interface between the semiconductor crystal and melt surface resulted from the applied magnetic field can be tuned during the growth of the semiconductor crystal, and effectively improve the uniformity of the temperature distribution of the silicon melt, thereby improving the uniformity of the crystal growth rate and the quality of crystal pulling.

### BRIEF DESCRIPTION OF THE DRAWINGS

Exemplary embodiments will be more readily understood from the following detailed description when read in conjunction with the appended drawings, in which:

FIGS. 1A and 1B are schematic diagrams of the temperature distribution below the interface between a crystal and a melt in a semiconductor crystal growth device;

FIG. 2 is a schematic structural diagram of a semiconductor crystal growth device according to the present invention;

FIG. 3 is a schematic cross-sectional positional arrangement of a crucible, a reflector, and a silicon crystal ingot in a semiconductor crystal growth apparatus according to an embodiment of the present invention;

FIG. 4 is a schematic diagram of the change in the distance between the bottom of the reflector of the semiconductor crystal growth apparatus and the silicon melt surface with the change of the angle α in FIG. 3 according to the embodiment of the present invention

FIG. 5 is a schematic structural diagram of a reflector in a semiconductor growth apparatus according to an embodiment of the present invention.

### DETAILED DESCRIPTION

The embodiments of the present invention are described below by way of specific examples, and those skilled in the art can readily understand other advantages and effects of the present invention from the disclosure of the present disclosure. The present invention may be embodied or applied in various other specific embodiments, and various modifications and changes can be made without departing from the spirit and scope of the invention.

In the following description, while the invention will be described in conjunction with various embodiments, it will be understood that these various embodiments are not intended to limit the invention. On the contrary, the invention is intended to cover alternatives, modifications and equivalents, which may be comprised within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details or with equivalents thereof. In other instances, well known methods, procedures, components, and circuits have not been described in detail as not to unnecessarily obscure aspects of the invention.

To understand the invention thoroughly, the following descriptions will provide detail steps to explain a method for crystal growth control of a shouldering process according to the invention. It is apparent that the practice of the invention is not limited to the specific details familiar to those skilled in the semiconductor arts. The preferred embodiment is described as follows. However, the invention has further embodiments beyond the detailed description.

The terminology used herein is for the purpose of describing particular embodiments only and is not intended to be limiting of example embodiments. As used herein, the singular forms “a,” “an” and “the” are intended to comprise the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Referring to FIG. 2, a schematic structural diagram of a semiconductor crystal growth device according to one embodiment of the present invention is shown. The semiconductor crystal growth device includes a furnace body 1, a crucible 11 is disposed in the furnace body 1, and a heater 12 is provided on the outer side of the crucible 11 for heating. The crucible 11 contains a silicon melt 13. The crucible 11 is composed of a graphite crucible and a quartz crucible sheathed in the graphite crucible. The graphite crucible receives the heat provided by the heater to melt the polycrystalline silicon material in the quartz crucible to form a silicon melt. Each quartz crucible is used for a batch semiconductor growth process, and each graphite crucible is used for a multi-batch semiconductor growth process.

A pulling device 14 is provided on the top of the furnace body 1. Driven by the pulling device 14, a seed crystal may be pulled and pulled out of a silicon ingot 10 from the silicon melt surface, and a heat shield device is provided around the silicon ingot 10. The heat shield device, for example, as shown in FIG. 1, comprises a reflector 16, which is provided in a barrel type, serves as a heat shield device to isolate the quartz crucible during the crystal growth process and the thermal radiation generated by the silicon melt in the crucible on the surface of the crystal increases the cooling rate and axial temperature gradient of the ingot, and increases the number of crystal growth. On the other hand, it affects the thermal field distribution on the surface of the silicon melt and avoids the axial temperature gradient between the center and the edge is too large to ensure stable growth between the crystal ingot and the silicon melt surface. At the same time, the baffle is also used to guide the inert gas introduced from the upper part of the crystal growth furnace to make it a large flow rate passes through the surface of the silicon melt to achieve the effect of controlling the oxygen content and impurity content in the crystal. During the growth of the semiconductor crystal, driven by the pulling device 14, the silicon ingot 10 passes vertically through the reflector 16.

In order to achieve stable growth of the silicon ingot, a driving device 15 for driving the crucible 11 to rotate and move up and down is provided at the bottom of the furnace body 1. The driving device 15 drives the crucible 11 to keep rotating during the crystal pulling process in order to reduce silicon melting. The thermal asymmetry of the body causes the silicon crystal columns to grow equally.

In order to hinder the convection of the silicon melt, increase the viscosity in the silicon melt, reduce impurities such as oxygen, boron, and aluminum from the quartz crucible into the melt and then into the crystal, so that the grown silicon crystal can have the controlled low-to-high range oxygen content reduces impurity streaks. The semiconductor growth device further comprises a magnetic field applying device 17 located outside the furnace body 1 to apply a magnetic field to the silicon melt in the crucible.

Since the magnetic field lines of the magnetic field applied by the magnetic field applying device 17 pass from one end of the silicon melt in the crucible to the other end in parallel (see the dotted arrow in FIG. 2), the Lorentz force generated by the rotating silicon melt is on the circumference. The directions are different, so the flow and temperature distribution of the silicon melt are inconsistent in the circumferential direction, where the temperature along the direction of the magnetic field is higher than that in the direction perpendicular to the magnetic field. The inconsistency of the flow and temperature of the silicon melt manifests as the temperature of the melt below the interface of the semiconductor crystal and the melt fluctuates with the change of the angle, so that the crystallization speed PS of the crystal fluctuates, so that the semiconductor growth speed appears inconsistent on the circumference. Such non-uniformity is not suited for the quality control of semiconductor crystal growth.

For this reason, in the semiconductor growth device of the present invention, the reflector 16 is arranged along the circumferential direction of the silicon ingot, and the bottom of the reflector and the silicon melt surface have different distances.

Along the circumference of the silicon ingot, a different distance is set between the bottom of the reflector and the silicon melt surface, and the distance between the bottom of the reflector and the silicon melt surface in the direction of the magnetic field is smaller than that of perpendicular in the direction of the magnetic field. The distance between the bottom of the reflector and the silicon melt surface in the direction of the magnetic field, where the distance is smaller, the silicon melt surface radiates more heat to the silicon ingot and the inside of the reflector. At a small distance, the heat from the silicon melt surface radiates more to the silicon ingot and the inside of the reflector, so that the temperature of the silicon melt surface at a shorter distance is lower than that of the silicon melt at a larger distance. The temperature of the body fluid surface is much reduced, making up for the problem that the temperature in the direction of the magnetic field application is higher than the temperature perpendicular to the direction of the magnetic field application due to the effect of the applied magnetic field on the silicon melt flow. According to this, by setting the distance between the bottom of the reflector and the silicon melt surface, the temperature distribution of the silicon melt below the interface between the silicon ingot and the silicon melt can be tuned, so that the temperature fluctuation caused by the applied magnetic field can be tuned. The fluctuation of the temperature distribution of the silicon melt in the circumferential direction effectively improves the uniformity of the temperature distribution of the silicon melt, thereby improving the uniformity of the speed of crystal growth and the quality of crystal pulling.

Meanwhile, along the circumferential direction of the silicon ingot, there is a different distance between the bottom of the reflector and the silicon melt surface, so that at a larger distance, the top of the furnace body communicates with the pressure and flow rate of the silicon melt surface flowing back through the reflector are increased, and the shear force of the silicon melt surface is increased. At a small distance, the top of the furnace body passes through the reflector, the pressure and flow rate at the position of the silicon melt surface reduced, and the shear force of the silicon melt surface reduced. Accordingly, by setting the distance between the bottom of the reflector and the melt surface, the structure is further tuned to make the flow state of the silicon melt more uniform along the circumferential direction, which further improves the uniformity of the crystal growth speed and the quality of the crystal pull. At the same time, by changing the flow state of the silicon melt, the uniformity of the oxygen content distribution in the crystal can be improved, and defects in crystal growth can be reduced.

Specifically, according to the present invention, the bottom of the reflector 16 is provided with downwardly convex steps, so that a distance between the bottom of the reflector and the silicon melt surface in the direction of the magnetic field is smaller than a distance between the bottom of the reflector and the silicon melt surface in a direction perpendicular to the magnetic field, so that the structure of the existing reflector is fully utilized without redesigning the reflector structure, and the technical effects of the present invention can be realized, and the production cost is effectively reduced.

According to an embodiment of the present invention, the steps are arranged on opposite sides of the reflector along the direction of the magnetic field. In accordance with some embodiments, the steps are arc-shaped steps and arranged along the circumferential direction of the reflector.

Referring to FIG. 3, there is shown a schematic cross-sectional positional arrangement of crucibles, reflectors, and silicon ingots in a semiconductor crystal growth apparatus according to an embodiment of the present invention. As shown in FIG. 3, the bottom of the reflector 16 is in a circular barrel shape, so that the bottom of the reflector 16 is an elliptical ring, in which, along the direction of application of the magnetic field (shown by arrow B in FIG. 3), the opposite sides of the reflector 16 are provided with downwardly convex steps 1601 and 1602. The steps 1601 and 1602 are arranged on the opposite sides of the bottom of the reflector 16 along the direction of the magnetic field, and the steps 1601 and 1602 are arc-shaped, so that along the direction of the magnetic field, the distance between the bottom of the reflector 16 and the silicon melt surface is smaller than the distance between the bottom of the reflector 16 and the silicon melt surface in a direction perpendicular to the magnetic field, so that in the direction of the magnetic field, the temperature of the silicon melt surface drops faster, so as to compensate for the defect that the temperature of the silicon melt is higher along the direction of the magnetic field caused by the application of a horizontal magnetic field, so that the temperature of the silicon melt is distributed along the circumference of the reflector more uniform.

It should be understood that in this embodiment, the downwardly convex steps are set to be arranged on the opposite sides of the reflector along the direction of the magnetic field, and the steps are set in an arc shape are purely exemplary, and those skilled in the art should understand that any steps arranged at the bottom of the reflector can make the distance between the bottom of the reflector and the silicon melt surface in the direction of applied the magnetic field smaller than in the direction perpendicular to the magnetic field can achieve the technical effect of the present invention.

Exemplarily, an angle corresponding to the arc-shaped steps is in the range of 20°-160°.

Exemplarily, a height of the steps is in the range of 2-20 mm.

Referring to FIG. 4, there is shown a schematic diagram of the change in the distance between the bottom of the reflector of the semiconductor crystal growth apparatus and the melt surface of the silicon melt according to the change of the angle α in FIG. 3 according to the embodiment of the present invention. The axis represents the distance between the bottom of the reflector and the melt surface of the silicon melt, and the horizontal axis represents the change of the position of the bottom of the reflector with the angle α in FIG. 3. When α is 90° and 270°, the distance between the bottom of the reflector and the melt surface of the silicon melt is smaller than when α is 0° and 180°, it is the distance between the bottom of the reflector and the silicon melt surface. When α is 90° and 270°, the bottom position of the reflector is in the direction of the magnetic field (as shown by arrow B in FIG. 3), when α is 0° and 180°, the bottom position of the reflector is perpendicular to the direction of the magnetic field. Among them, when α is 0°, it is the distance H₀ between the bottom of the reflector and the silicon melt surface, and when α is 90°, it is the distance between the bottom of the reflector and the melt surface of the silicon melt H₀ and H₉₀. The difference h between them is the height of the steps, and the range is 2-20 mm. Since the arc-shaped steps are arranged along the circumference, the corresponding central angle W ranges from 20° to 160°. Since the bottom of the reflector is arranged with steps, rounded corners are applied to the joints of the steps. Illustratively, the radius of the rounded corners is 1-5 mm.

In one embodiment of the present invention, the reflector comprises an inner cylinder, an outer cylinder and a heat-insulation material, in which a bottom of the outer cylinder is extended below a bottom of the inner cylinder and is closed with the bottom of the inner cylinder to form a cavity between the inner cylinder and the outer cylinder, and the heat-insulation material is disposed in the cavity.

In one embodiment, the bottom of the outer cylinder has different wall thicknesses to form downwardly convex steps at the bottom of the reflector. Referring to FIG. 5, there is shown a schematic structural diagram of a reflector in a semiconductor growth apparatus according to an embodiment of the present invention. Referring to FIG. 5, the reflector 16 comprises an inner cylinder 161, an outer cylinder 162, and a heat insulating material 163 disposed between the inner cylinder 161 and the outer cylinder 162, wherein a bottom of the outer cylinder 162 extends below the bottom of the inner cylinder 161 and it is closed with the bottom of the inner cylinder 161 to form a cavity for containing the heat insulation material 163 between the inner cylinder 161 and the outer cylinder 162. Setting the reflector into a structure including an inner cylinder, an outer cylinder, and a heat insulating material can simplify the installation of the reflector. Exemplarily, the material of the inner cylinder and the outer cylinder is set to graphite, and the heat insulation material comprises glass fiber, asbestos, rock wool, silicate, aerogel felt, vacuum plate, and the like.

By setting the bottom of the outer cylinder to have different wall thicknesses to form the downwardly convex steps of the bottom of the reflector, the setting of the reflector steps is realized only by the arrangement of the outer cylinder, which simplifies the manufacturing process of the steps and reduces cost of production.

According to an embodiment of the present invention, the reflector comprises a tuning device for tuning the distance between the reflector and the silicon melt surface. By adopting an additional tuning device to change the distance between the reflector and the silicon melt surface, the manufacturing process of the reflector can be simplified on the existing reflector structure.

With continued reference to FIG. 5, the tuning device comprises an inserting part 18, the inserting part 18 comprises a protruding portion 181 and an inserting portion 182 which are provided to be inserted between the bottom of the outer cylinder 162 and a portion extended below the bottom of the inner cylinder 161 and the bottom of the inner cylinder 161. The protruding portion 181 is extended to cover the bottom of the outer cylinder 162.

Since the existing reflector is generally set in a conical barrel shape, the bottom of the reflector is usually set with a circular cross section, and the reflector is set to include between the inner cylinder and the outer cylinder without changing the structure of the existing reflector, the shape of the bottom of the reflector can be flexibly tuned by tuning the structure and shape of the inserting part without changing the structure of the existing reflector to tune the distance between the reflector and the silicon melt surface; without changing the existing semiconductor growth device, the effect of the present invention can be achieved by arranging a tuning device with an inserting part. At the same time, the inserting parts can be manufactured and replaced in a modular manner, so as to adapt to various semiconductor crystal growth processes of different sizes, thereby saving costs.

The inserting part is installed on the reflector in the form of an insert, without the need to modify the reflector, the installation of the tuning device can be realized, and the manufacturing and installation costs of the tuning device and the reflector are further simplified. At the same time, the position where the inserting part is inserted between the bottom of the outer cylinder and the bottom of the inner cylinder effectively reduces the heat conduction from the outer cylinder to the inner cylinder, reduces the temperature of the inner cylinder, and further reduces the radiant heat transfer from the inner cylinder to the ingot, effectively. The difference between the axial temperature gradient of the center and the periphery of the silicon ingot is reduced, and the quality of the crystal pulling is improved. Exemplarily, the tuning device is employed a material with low thermal conductivity, such as SiC ceramic, quartz, or the like.

Exemplarily, the tuning device may be arranged in sections, such as two arranged on the reflector along the direction of the magnetic field, so that the protruding portion constitutes steps; or it is arranged along the circumference of the bottom of the reflector, such as an elliptical ring, and steps are arranged on the protruding portion.

It should be understood that the setting of the tuning device in sections or in an elliptical ring is only exemplary, and any tuning devices which are capable of tuning the distance between the reflector and the silicon melt surface are applicable to the present invention.

The above is an exemplary introduction to the semiconductor crystal growth device according to the present invention. According to the semiconductor crystal growth device of the present invention, the bottom of the reflector is provided with downwardly convex steps to make the distance between the bottom of the reflector and the silicon melt surface in the direction of the magnetic field is smaller than a distance between the bottom of the reflector and the silicon melt surface in the direction perpendicular to the magnetic field, so that the temperature distribution of the silicon melt under the interface between the silicon ingot and the silicon melt plays a role in regulating, so that the fluctuation of the silicon melt temperature in the circumferential direction caused by the applied magnetic field can be tuned, which effectively improves the uniformity of the silicon melt temperature distribution, thereby improving the uniformity of crystal growth speed and improving the quality of crystal pulling. At the same time, the flow structure of the silicon melt is tuned to make the flow state of the silicon melt more uniform along the circumferential direction, which further improves the uniformity of crystal growth speed and reduces crystal growth defects.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A semiconductor crystal growth apparatus, comprising:
a furnace body;
a crucible being arranged inside the furnace body to contain a silicon melt;
a pulling device being arranged on the top of the furnace body and used for pulling out a silicon ingot rod from the silicon melt;
a reflector being barrel-shaped and disposed above the silicon melt in the furnace body in a vertical direction,
wherein the pulling device pulls the silicon ingot through the reflector in a vertical direction; and
a magnetic field applying device for applying a horizontal magnetic field to the silicon melt in the crucible;
wherein the bottom of the reflector is provided with downwardly convex steps, so that a distance between the bottom of the reflector and the silicon melt surface in the direction of the magnetic field is smaller than a distance between the bottom of the reflector and the silicon melt surface in a direction perpendicular to the magnetic field.

2. The apparatus according to claim 1, wherein the steps are arranged on opposite sides of the reflector along the direction of the magnetic field.

3. The apparatus according to claim 2, wherein the steps are arc-shaped steps and arranged along the circumferential direction of the reflector.

4. The apparatus according to claim 3, wherein an angle corresponding to the arc-shaped steps is in the range of 20°-160°.

5. The apparatus according to claim 1, wherein a height of the steps is in the range of 2-20 mm.

6. The apparatus according to claim 1, wherein the reflector comprises an inner cylinder, an outer cylinder, and a heat insulating material; wherein the bottom of the outer cylinder is extended below the bottom of the inner cylinder and is closed to the bottom of the inner cylinder to form a cavity between the inner cylinder and the outer cylinder, and the heat insulation material is disposed in the cavity.

7. The apparatus according to claim 6, wherein the bottom of the outer cylinder has different wall thicknesses to form the downwardly convex steps at the bottom of the reflector.

8. The apparatus according to claim 6, wherein the reflector comprises an inserting part, the inserting part comprises a protruding portion and an inserting portion, and the inserting portion is inserted between a portion of the bottom of the outer cylinder extended below the bottom of the inner cylinder and the bottom of the inner cylinder, and the protruding portion is extended to cover the bottom of the outer cylinder.

9. The apparatus according to claim 8, wherein the protruding portion comprises two sections disposed on opposite sides of the reflector along the direction of the magnetic field, and the protruding portion constitutes the steps.

10. The apparatus according to claim 8, wherein the protruding portion is ring-shaped and covers the bottom of the reflector, and the steps are located on the protruding portion.
